(19) United States
(12) Patent Application Publication
(10) Pub. No.: US 2025/0151235 A1
(43) Pub. Date: May 8, 2025

(54) REFRIGERATION APPARATUS AND DATA CENTER

(71) Applicant: Hebei Qinhuai Data Co., Limited., Zhangjiakou City (CN)

(72) Inventor: Binghua ZHANG, Zhangjiakou City (CN)

(21) Appl. No.: 18/937,036

(22) Filed: Nov. 5, 2024

(30) Foreign Application Priority Data
Nov. 8, 2023 (CN) 202311483190.2

(51) Int. Cl. H05K 7/20

(52) U.S. Cl. CPC H05K 7/20354; H05K 7/20745

(57) ABSTRACT

The present disclosure discloses a refrigeration apparatus and a data center, where the refrigeration apparatus includes a primary heat exchanger and a secondary heat exchanger. Both the primary heat exchanger and the secondary heat exchanger are arranged in a first air duct forming an air circuit together with an inner cavity of the machine room, and the secondary heat exchanger is positioned downstream of the primary heat exchanger. The primary heat exchanger is connected in series to a first refrigeration circuit, and the first refrigeration circuit is cooled down by means of liquid cooling. The secondary heat exchanger is connected in series to a second refrigeration circuit, and at least a portion of the second refrigeration circuit is refrigerated by means of a compressor.

### CROSS REFERENCE TO RELATED APPLICATION

This application claims priority to Chinese Patent Application No. 202311483190.2, titled “REFRIGERATION APPARATUS AND DATA CENTER” and filed to the China National Intellectual Property Administration on Nov. 8, 2023, the entire contents of which are incorporated herein by reference.

### TECHNICAL FIELD

Embodiments of the present disclosure relate to the field of data center refrigeration technology, and more particularly, to a refrigeration apparatus and a data center.

### BACKGROUND

With the development of intelligent technologies, processing capacity of digital information is rapidly increasing. In the face of rapidly growing business demands and users' huge expectations to data processing and information exchange, generally number of IT devices in data centers is increased to meet the users' requirements for information network systems in terms of technical performance, data processing capacity, storage capacity, and utilization rate, etc. However, this may lead to increase in heat density of the data centers.

A related refrigeration device for a data center includes a compressor, a condenser, and an evaporator that form a circuit through pipelines. Heat transfer media such as refrigerants may circulate in the circuit under the guidance of a pump body. Specifically, a low-pressure gaseous heat transfer medium is drawn into the compressor and compressed into a high-temperature and high-pressure gaseous heat transfer medium. The gaseous heat transfer medium flows into the condenser and gradually condenses into a high-pressure liquid heat transfer medium during a heat dissipation process. The high-pressure liquid heat transfer medium is then reduced in pressure (and also is cooled down) through a throttle valve and turns into a low-temperature and low-pressure gas-liquid heat transfer medium mixture. The gas-liquid heat transfer medium mixture enters the evaporator and continuously vaporizes by absorbing heat from air, causing temperature of the air flowing through the evaporator to decrease, and the heat transfer medium turns into a low-pressure gas again and reenters the compressor. This cycle repeats.

However, the above-mentioned refrigeration device has the disadvantage of high energy consumption.

### SUMMARY

Objectives of embodiments of the present disclosure are to provide a refrigeration apparatus and a data center, which can solve the problem of high energy consumption.

To achieve the above objectives, one aspect of the embodiments of the present disclosure provides a refrigeration apparatus for a machine room. The refrigeration apparatus includes a primary heat exchanger and a secondary heat exchanger, where both the primary heat exchanger and the secondary heat exchanger are arranged in a first air duct forming an air circuit together with an inner cavity of the machine room, and the air circuit is provided for air to flow through. The secondary heat exchanger is positioned downstream of the primary heat exchanger. The primary heat exchanger is connected in series to a first refrigeration circuit, where the first refrigeration circuit is provided for a first cooling medium to flow through and is cooled down by means of liquid cooling. The secondary heat exchanger is connected in series to a second refrigeration circuit, the second refrigeration circuit is provided for a second cooling medium to flow through, and at least a portion of the second refrigeration circuit is refrigerated by means of a compressor.

Alternatively, the primary heat exchanger has a first inflow end and a first outflow end, and the first inflow end and/or the first outflow end of the primary heat exchanger are provided with a first shut-off valve, which is configured to shut off the first refrigeration circuit when a temperature outside the machine room is lower than a preset temperature.

Alternatively, the refrigeration apparatus also includes an intermediate heat exchanger, which is arranged in the first air duct. The intermediate heat exchanger is connected in series to a third refrigeration circuit provided for a third cooling medium to flow through, and the third refrigeration circuit is cooled down by means of cooling of air outside the machine room.

Alternatively, the intermediate heat exchanger has a third inflow end and a third outflow end, and the third inflow end and/or the third outflow end of the secondary heat exchanger are provided with a second shut-off valve, which is configured to switch on the third refrigeration circuit when the temperature outside the machine room is lower than a temperature inside the machine room.

Alternatively, the third refrigeration circuit includes a first outdoor heat exchanger and a power pump, and the second refrigeration circuit includes a second outdoor heat exchanger and a compressor. Both the first outdoor heat exchanger and the second outdoor heat exchanger are arranged in a second air duct, where two open ends of the second air duct are both communicated with an outer side of the machine room.

Alternatively, the intermediate heat exchanger is positioned upstream of the secondary heat exchanger, and/or the second outdoor heat exchanger is positioned upstream of the first outdoor heat exchanger.

Alternatively, the second refrigeration circuit includes an outdoor heat exchanger, a compressor, and a fluorine pump. The compressor and the fluorine pump are connected in parallel to the second refrigeration circuit, and the compressor and the fluorine pump are configured to not start up simultaneously. When a temperature inside the machine room is lower than a first warning temperature and the temperature outside the machine room is lower than the temperature inside the machine room, the fluorine pump is communicated between the secondary heat exchanger and the outdoor heat exchanger. When the temperature outside the machine room is higher than the temperature inside the machine room, the compressor is communicated between the secondary heat exchanger and the outdoor heat exchanger.

Alternatively, the compressor is connected in series between an outflow end of the secondary heat exchanger and an inflow end of the outdoor heat exchanger. The fluorine pump is connected in series between an outflow end of the outdoor heat exchanger and an inflow end of the secondary heat exchanger. Two ends of the fluorine pump are connected in parallel to a third shut-off valve, and two ends of the compressor are connected in parallel to a fourth shut-off valve, where the third shut-off valve and the fourth shut-off valve do not carry out a shut-off operation simultaneously.

Alternatively, the refrigeration apparatus also includes a filter, which is arranged in the first air duct and is configured to filter air flowing therethrough.

To achieve the above objectives, another aspect of the embodiments of the present disclosure also provides a data center, which includes a server and the refrigeration apparatus as mentioned above, where the server is arranged in the inner cavity of the machine room. The primary heat exchanger and the secondary heat exchanger of the refrigeration apparatus are both arranged in the first air duct forming the air circuit together with the inner cavity of the machine room.

To sum up, in the refrigeration apparatus and the data center provided in the embodiments of the present disclosure, the primary heat exchanger and the secondary heat exchanger are arranged in the first air duct forming the air circuit together with the inner cavity of the machine room. The primary heat exchanger is connected in series to the first refrigeration circuit cooled down by means of liquid cooling, and the secondary heat exchanger is connected in series to the second refrigeration circuit refrigerated by means of the compressor. When the temperature inside the machine room is lower, the first refrigeration circuit may be turned on and the second refrigeration circuit may be turned off. When the temperature inside the machine room is higher, both the first refrigeration circuit and the second refrigeration circuit may be turned on. Because the secondary heat exchanger is positioned downstream of the primary heat exchanger, hot air may be first cooled down by the primary heat exchanger before passing through the secondary heat exchanger, which can reduce power of the compressor, reduce power distribution capacity, reduce consumption of electricity, and reduce investment costs.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram of a data center according to an embodiment of the present disclosure;

FIG. 2 is a schematic diagram of a refrigeration apparatus according to an embodiment of the present disclosure; and

FIG. 3 is a schematic diagram of another refrigeration apparatus according to an embodiment of the present disclosure.

Reference numerals in the accompanying drawings:
refrigeration apparatus 1000;
first refrigeration circuit 100; primary heat exchanger 110; cooling device 120;
second refrigeration circuit 200; secondary heat exchanger 210; outdoor heat exchanger 220; compressor 230; fluorine pump 240; second outdoor heat exchanger 250; second compressor 260;
third refrigeration circuit 300; intermediate heat exchanger 310; first outdoor heat exchanger 320; power pump 330;
first air duct 410; second air duct 420;
first shut-off valve 510; second shut-off valve 520; third shut-off valve 530; fourth shut-off valve 540; fifth shut-off valve 550;
filter 600;
first fan 710; second fan 720; and
machine room 2000.

### DETAILED DESCRIPTION

As mentioned in the background technology, refrigeration devices in related technologies have the disadvantage of higher energy consumption. In response to the above disadvantage, embodiments of the present disclosure provide a refrigeration apparatus and a data center. A primary heat exchanger and a secondary heat exchanger are arranged in a first air duct forming an air circuit together with an inner cavity of a machine room. The primary heat exchanger is connected in series to a first refrigeration circuit cooled down by means of a natural cold resource, and the secondary heat exchanger is connected in series to a second refrigeration circuit refrigerated by means of a compressor. When temperature inside the machine room is lower, the first refrigeration circuit may be turned on and the second refrigeration circuit may be turned off. When the temperature inside the machine room is higher, both the first refrigeration circuit and the second refrigeration circuit may be turned on. Because the secondary heat exchanger is positioned downstream of the primary heat exchanger, hot air may be first cooled down by the primary heat exchanger before passing through the secondary heat exchanger, which can reduce power of the compressor, reduce power distribution capacity, reduce consumption of electricity, and reduce investment costs.

To make the objectives, technical solutions, and advantages of the embodiments of the present disclosure clearer, the technical solutions in the embodiments of the present disclosure will be described clearly and completely below with reference to the accompanying drawings in the embodiments of the present disclosure. Apparently, the described embodiments are some but not all of the embodiments of the present disclosure.

All other embodiments obtained by a person of ordinary skill in the art based on the embodiments of the present disclosure without creative efforts shall fall within the protection scope of the present disclosure. The following embodiments and features thereof may be combined with each other on a non-conflict basis.

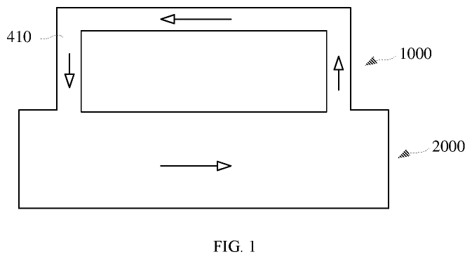

FIG. 1 is a schematic diagram of a data center according to an embodiment of the present disclosure. Referring to FIG. 1, the data center provided in the embodiments of the present disclosure may include a refrigeration apparatus 1000 and a server. The server is arranged in an inner cavity of a machine room 2000, and the inner cavity of the machine room 2000 may be communicated with a first air duct 410 to form an air circuit, which is provided for air to flow.

The refrigeration apparatus 1000 may include a shell body or pipe body, where the shell body or pipe body may have a first air duct 410. Alternatively, the first air duct 410 is formed by a pipe body other than the refrigeration apparatus 1000 or a shell body of other apparatus. Alternatively, some first air ducts 410 may be formed by the refrigeration apparatus 1000, and some first air ducts 410 may be formed by other pipe bodies or shell bodies of other apparatuses.

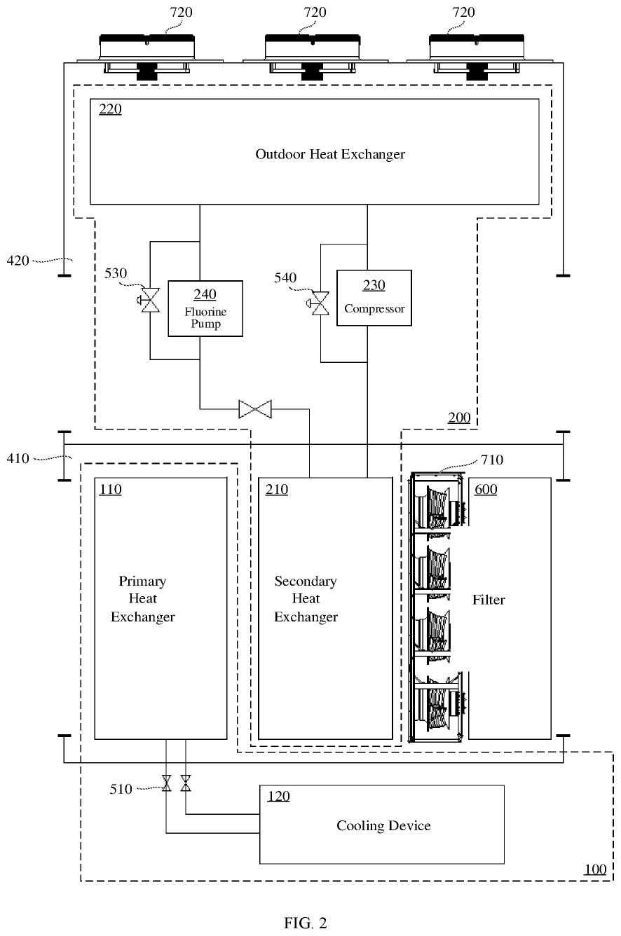

Hollow arrows in FIG. 1 indicate flow directions of air. Referring to FIG. 1, for example, the machine room 2000 may have an air inlet and an air outlet communicated with each other through the inner cavity of the machine room 2000. Two open ends of the first air duct 410 may be communicated with the air inlet and the air outlet of the machine room 2000, respectively. The air in the first air duct 410 may flow into the inner cavity of the machine room 2000 through the air inlet, and the air in the inner cavity of the machine room 2000 may flow into the first air duct 410 through the air outlet. In this way, the first air duct 410 forms an annular air circuit together with the inner cavity of the machine room 2000. The air may circulate in the air circuit under the action of a first fan 710 as mentioned below (shown in FIG. 2). FIG. 1 is shown as an example where the first air duct 410 is arranged on an outer side of the inner cavity of the machine room 2000. Of course, the first air duct 410 may also be arranged in the inner cavity of the machine room 2000, as long as it is ensured that the first air duct 410 can form the air circuit together with the inner cavity of the machine room 2000.

FIG. 2 is a schematic diagram of a refrigeration apparatus 1000 according to an embodiment of the present disclosure. Referring to FIG. 2, the refrigeration apparatus 1000 may include a primary heat exchanger 110 and a secondary heat exchanger 210, where both the primary heat exchanger 110 and the secondary heat exchanger 210 may be arranged in the first air duct 410. To reduce temperature by means of heat exchange when the air flows through the primary heat exchanger 110 and the secondary heat exchanger 210, a first cooling medium having a lower temperature may flow in the primary heat exchanger 110, and a second cooling medium having a lower temperature may flow in the secondary heat exchanger 210.

To maintain the lower temperature of the first cooling medium in the primary heat exchanger 110, the primary heat exchanger 110 may be connected in series to a first refrigeration circuit 100, which may be cooled down by means of liquid cooling. Specifically, the primary heat exchanger 110 may be communicated with a cooling device 120 to form the first refrigeration circuit 100. For example, the primary heat exchanger 110 may have a first inflow end and a first outflow end. The first inflow end of the primary heat exchanger 110 may be communicated with an outflow end of the cooling device 120 through a pipe body or may be directly communicated with the outflow end of the cooling device 120. The first outflow end of the primary heat exchanger 110 may be communicated with an inflow end of the cooling device 120 through the pipe body or may be directly communicated with the inflow end of the cooling device 120.

In addition, a power apparatus such as a pump may be arranged in the first refrigeration circuit 100, and can drive the first cooling medium in the first refrigeration circuit 100 to circulate. When the hotter air in the first air duct passes through the primary heat exchanger 110, the first cooling medium in the primary heat exchanger 110 may exchange heat with the hotter air to rise in temperature. The first cooling medium whose temperature has risen may be cooled down when flowing through the cooling device 120, and the cooled first cooling medium will enter the primary heat exchanger 110 again to exchange heat with the hotter air. The cooling device 120 mentioned above may be a device, such as a cooling tower, that can reduce water temperature. The cooling tower is a device for cooling water by means of contact (direct or indirect) between air and water.

In addition, the first cooling medium may be single-phase or two-phase. When the first cooling medium is single-phase, the first cooling medium may maintain a single liquid state in its circulation in the first refrigeration circuit 100, and may be classified into two types: a water-based cooling medium and a nonwater-based cooling medium. The water-based cooling medium may include: pure water, softened water, a certain proportion (0% to 60%) of antifreeze added into the pure water, and a functional additive such as an inhibitor or biocide added into the pure water. When the water-based cooling medium is mixed liquor, periodic sampling may be made to test conditions of the additive. In addition, the nonwater-based cooling medium generally is a dielectric liquid such as hydrofluoroether and perfluorocarbon whose boiling point is not lower than that of water, or mineral oil. When in use, strict review and testing should be conducted on compatibility of wetted materials. In addition, when the first cooling medium is two-phase, the first cooling medium may undergo gas-liquid two-phase conversion in its circulation in the first refrigeration circuit 100. Typically having a lower boiling point, the two-phase cooling medium absorbs heat mainly from latent heat of vaporization of a liquid, to form a two-phase flow carrying heat in the circulation. The two-phase cooling medium generally is a dielectric liquid or refrigerant. Different two-phase cooling mediums generally have different boiling points.

In addition, the first inflow end and/or the first outflow end of the primary heat exchanger 110 may be provided with a first shut-off valve 510, and the first shut-off valve 510 can turn on or off the first refrigeration circuit 100. Because the first refrigeration circuit 100 is cooled down by means of liquid cooling, the first cooling medium in the first refrigeration circuit 100 may be frozen in colder winter. To avoid this situation from happening, when the temperature outside the machine room 2000 is lower than a preset temperature, the first refrigeration circuit 100 may be turned off by means of the first shut-off valve 510. Simultaneously, the pump and the cooling device 120 of the first refrigeration circuit 100 stop running. In addition, when the temperature outside the machine room 2000 is not lower than the preset temperature, the first refrigeration circuit 100 may be turned on by means of the first shut-off valve 510. Simultaneously, the pump and the cooling device 120 of the first refrigeration circuit 100 are in an operating state.

The first shut-off valve 510 may be electrically connected to a controller and is regulated and controlled by the controller. A temperature sensor can detect the temperature outside the machine room 2000, convert the temperature outside the machine room 2000 into an electrical signal, and send the electrical signal to the controller. The controller can receive the electrical signal sent by the temperature sensor, determine whether the temperature outside the machine room 2000 is lower than a first preset temperature, and produce a control signal. The first shut-off valve 510 can receive the control signal and turn on or off the first refrigeration circuit 100. Hereinbefore, the controller obtains the temperature outside the machine room 2000 by means of the temperature sensor. In addition, the controller may also obtain a temperature of an area where the machine room 2000 is positioned through networking.

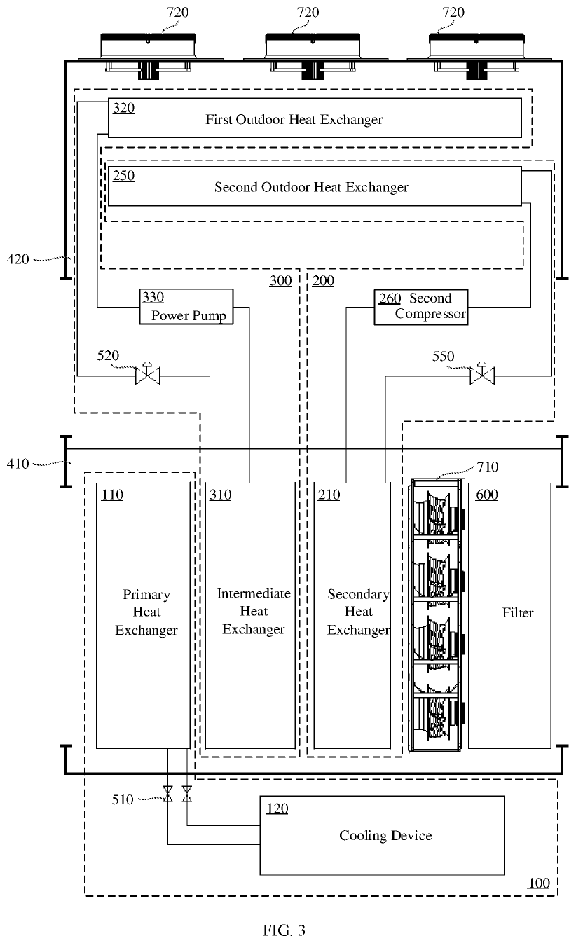

With continued reference to FIG. 2, to maintain the lower temperature of the second cooling medium in the secondary heat exchanger 210, the secondary heat exchanger 210 may be connected in series to the second refrigeration circuit 200, and at least a portion of the second refrigeration circuit 200 may refrigerate by means of the compressor 230. For example, in FIG. 2, the second refrigeration circuit may include two smaller refrigeration circuits, where one smaller refrigeration circuit refrigerates by means of the compressor 230, and the other smaller refrigeration circuit refrigerates by means of air cooling dominated by a fluorine pump 240. In FIG. 3, the second refrigeration circuit refrigerates completely by means of the compressor 230.

To reduce power consumption of the compressor 230, the secondary heat exchanger 210 may be positioned downstream of the primary heat exchanger 110, such that the air flowing into the first air duct 410 can sequentially pass through the primary heat exchanger 110 and the secondary heat exchanger 210 before flowing out of the first air duct 410. In addition, when the temperature inside the machine room 2000 is lower, the first refrigeration circuit 100 may be turned on and the second refrigeration circuit 200 may be turned off. When the temperature inside the machine room 2000 is higher, both the first refrigeration circuit 100 and the second refrigeration circuit 200 may be turned on. In addition, because the secondary heat exchanger 210 is positioned downstream of the primary heat exchanger 110, the hot air may first be cooled down by the primary heat exchanger 110 and then is cooled down by the secondary heat exchanger 210, to reduce the power of the compressor 230, reduce the power distribution capacity, reduce the consumption of electricity, and reduce the investment costs.

As mentioned above, in colder winter, the first refrigeration circuit 100 may be turned off by means of the first shut-off valve 510. To reduce the power consumption of the refrigeration apparatus 1000 in winter, two following feasible implementation manners may be adopted.

In one feasible implementation manner, referring to FIG. 2, the second refrigeration circuit 200 may also include the fluorine pump 240, and the fluorine pump 240 may be connected in parallel to the compressor 230 in the second refrigeration circuit 200. The compressor 230 and the fluorine pump 240 are configured to not start up simultaneously. That is, when the fluorine pump 240 starts up, the compressor 230 does not start up. When compressor 230 starts up, the fluorine pump 240 does not start up.

When the temperature inside the machine room 2000 is lower than a first warning temperature and the temperature outside the machine room 2000 is lower than the temperature inside the machine room 2000, the fluorine pump 240 may be communicated between the secondary heat exchanger 210 and the outdoor heat exchanger 220. In this case, the air may pass through the secondary heat exchanger 210 and exchange heat with the second cooling medium in the secondary heat exchanger 210, causing the second cooling medium to rise in temperature. The second cooling medium whose temperature has risen will flow into the outdoor heat exchanger 220 under the action of the fluorine pump 240, and exchange heat with the air outside the machine room 2000 to cool down the second cooling medium. The cooled second cooling medium will enter the secondary heat exchanger 210 again to rise in temperature.

It should be noted that when the temperature inside the machine room 2000 is equal to or higher than the first warning temperature, this indicates that the temperature inside the machine room 2000 is higher, and the machine room 2000 needs to be cooled down quickly. Because compression cooling is faster in speed and higher in efficiency than air cooling, the compressor 230 may be communicated between the secondary heat exchanger 210 and the outdoor heat exchanger 220 in this case. In addition, when the temperature outside the machine room 2000 is higher than the temperature inside the machine room 2000, this indicates that the air outside the machine room 2000 cannot be used as a cold source. Therefore, in this case, the compressor 230 may be communicated between the secondary heat exchanger 210 and the outdoor heat exchanger 220.

In addition, there are a variety of ways to connect the compressor 230 in parallel to the fluorine pump 240 in the second refrigeration circuit 200. As an example, the compressor 230 and the fluorine pump 240 may be arranged on two branches connected in parallel with each other, and each branch may be provided with one shut-off valve for turning on or off this branch. As another example, referring to FIG. 2, the compressor 230 may be connected in series between the outflow end of the secondary heat exchanger 210 and the inflow end of the outdoor heat exchanger 220, and two ends of the compressor 230 are connected in parallel with a fourth shut-off valve 540. The fluorine pump 240 may be connected in series between the outflow end of the outdoor heat exchanger 220 and the inflow end of the secondary heat exchanger 210, two ends of the fluorine pump 240 are connected in parallel with a third shut-off valve 530, and the third shut-off valve 530 and the fourth shut-off valve 540 do not carry out a shut-off operation simultaneously.

It is worth noting that in the compressor refrigeration, the compressor 230 and a throttling element (such as an expansion valve or capillary tube) both participate in changing volume of the second cooling medium. Neither the compressor 230 nor the throttling element is effective for air cooling by means of the fluorine pump 240. It is mainly described above an arrangement manner of the compressor 230 in a conversion between the compressor refrigeration and the air cooling. Reference may be made to design of the compressor 230 for an arrangement manner of the expansion valve (or capillary tube) in the conversion between the compressor refrigeration and the air cooling, which is not to be described in detail here.

Referring to FIG. 3, in another feasible implementation manner to reduce the power consumption of the refrigeration apparatus 1000 in winter, the refrigeration apparatus 1000 provided in the embodiments of the present disclosure may also include an intermediate heat exchanger 310, which may be arranged in the first air duct 410. In addition, the intermediate heat exchanger 310 may be connected in series to the third refrigeration circuit 300, where the third refrigeration circuit 300 is provided for a third cooling medium to flow through, and the third refrigeration circuit 300 may be cooled down by means of cooling of air outside the machine room 2000.

Specifically, the third cooling medium may be single-phase or two-phase. The first outdoor heat exchanger 320, the power pump 330 and the intermediate heat exchanger may be communicated to form the third refrigeration circuit 300. For example, the intermediate heat exchanger 310 may have a third inflow end and a third outflow end. The third inflow end of the intermediate heat exchanger 310 may be communicated with the outflow end of the first outdoor heat exchanger 320 through a pipe body, and the third outflow end of the intermediate heat exchanger 310 may be communicated with the inflow end of the first outdoor heat exchanger 320 through the pipe body. The power pump 330 may be connected in series between the third inflow end of the intermediate heat exchanger 310 and the outflow end of the first outdoor heat exchanger 320, or the power pump 330 may be connected in series between the third outflow end of the intermediate heat exchanger and the inflow end of the first outdoor heat exchanger 320, and the power pump 330 can drive the third cooling medium to circulate in the third refrigeration circuit 300.

In addition, the first outdoor heat exchanger 320 may be arranged in a second air duct 420. A second fan 720 can guide the air outside the machine room 2000 to flow into the second air duct 420 through one open end of the second air duct 420. After exchanging heat with the first outdoor heat exchanger 320, the air flows out of the second air duct 420 through the other open end of the second air duct 420. When the hotter air flows through the intermediate heat exchanger 310, the third cooling medium in the intermediate heat exchanger 310 may exchange heat with the hot air in the first air duct 410 and rise in temperature. The third cooling medium whose temperature has risen may be cooled down by exchanging heat with the cold air in the second air duct 420 when flowing through the first outdoor heat exchanger 320. The cooled third cooling medium enters the intermediate heat exchanger 310 again and rises in temperature.

Alternatively, the third inflow end and/or third outflow end of the secondary heat exchanger 210 may be provided with a second shut-off valve 520, which can turn on or off the third refrigeration circuit 300. When the temperature outside the machine room 2000 is lower than the temperature inside the machine room 2000, the third refrigeration circuit 300 may be turned on by means of the second shut-off valve 520. Meanwhile, the power pump 330 of the third refrigeration circuit 300 is in an operating state. In addition, when the temperature outside the machine room 2000 is not lower than the temperature inside the machine room 2000, the third refrigeration circuit 300 may be turned off by means of the second shut-off valve 520. Meanwhile, the power pump 330 of the third refrigeration circuit 300 stops running.

The second shut-off valve 520 may be electrically connected to a controller and is regulated and controlled by the controller. The controller can determine, based on the temperature outside and inside the machine room 2000 detected by the temperature sensor, whether the temperature outside the machine room 2000 is lower than the temperature inside the machine room 2000, and control to turn on the second shut-off valve 520 or turn off the third refrigeration circuit 300 according to a determination result. The temperature outside the machine room 2000 is obtained by means of the temperature sensor. In addition, the temperature of the area where the machine room 2000 is positioned may be obtained through networking.

The second outdoor heat exchanger 250, the compressor 230 and the secondary heat exchanger 210 may be communicated to form the second refrigeration circuit 200. For example, the secondary heat exchanger 210 may have a third inflow end and a third outflow end. The third inflow end of the secondary heat exchanger 210 may be communicated with the outflow end of the second outdoor heat exchanger 250 through a pipe body, and the third outflow end of the secondary heat exchanger 210 may be communicated with the inflow end of the second outdoor heat exchanger 250 through the pipe body. The pump body may be arranged in the second refrigeration circuit 200 and can drive the second cooling medium to circulate in the second refrigeration circuit 200. In addition, the second outdoor heat exchanger 250 may be arranged in the second air duct 420. The second fan 720 can guide the air outside the machine room 2000 to flow into the second air duct 420 through one open end of the second air duct 420. After exchanging heat with the second outdoor heat exchanger 250, the air flows out of the second air duct 420 through the other open end of the second air duct 420. The second cooling medium vaporizes in the secondary heat exchanger 210 and absorbs heat from the hot air in the first air duct 410, and turns it into a low-pressure gas. A low-pressure gaseous second heat transfer medium enters the compressor 230 again and is compressed into a high-temperature and high-pressure gas. The high-temperature and high-pressure gaseous second heat transfer medium enters the second outdoor heat exchanger 250 again and exchanges heat with the air in the second air duct 420, and condenses into a high-pressure liquid. The high-pressure liquid second heat transfer medium is reduced in pressure and cooled by the throttle element, and turns into a low-temperature and low-pressure gas-liquid state. The low-temperature and low-pressure gas-liquid second heat transfer medium enters the secondary heat exchanger 210 again.

Alternatively, the third inflow end and/or third outflow end of the secondary heat exchanger 210 may be provided with a fifth shut-off valve 550, which can turn on or off the second refrigeration circuit 200.

Alternatively, the second outdoor heat exchanger 250 is positioned upstream of the first outdoor heat exchanger 320, to reduce the energy consumption of the second refrigeration circuit 200 when the second refrigeration circuit 200 and the third refrigeration circuit 300 are simultaneously turned on.

Alternatively, the intermediate heat exchanger 310 may be positioned upstream of the secondary heat exchanger 210, such that the air entering the first air duct 410 may first pass through the intermediate heat exchanger 310, then pass through the secondary heat exchanger 210, and finally flow out of the first air duct 410. When the temperature outside the machine room 2000 is lower than the preset temperature, the first refrigeration circuit 100 is turned off. When the temperature outside the machine room 2000 is lower than the temperature inside the machine room 2000, the third refrigeration circuit 300 may be turned on. When the temperature inside the machine room 2000 is higher than a limit that can be controlled by the third refrigeration circuit 300, both the third refrigeration circuit 300 and the second refrigeration circuit 200 may be turned on. The air may be cooled first by the intermediate heat exchanger 310 and then may be cooled by the secondary heat exchanger 210 to reduce the energy consumption of the second refrigeration circuit 200 during operation. When the temperature outside the machine room 2000 is not lower than the temperature inside the machine room 2000, the second refrigeration circuit 200 may be turned on.

Referring to FIG. 2 and FIG. 3, the refrigeration apparatus 1000 provided in the embodiments of the present disclosure may also include a filter 600, which may be arranged in the first air duct 410 and can filter the air flowing therethrough.

The terms such as “upper” and “lower” configured to describe relative positional relationships of various structures in the drawings are merely for the purpose of concise description rather than limiting the implementable scope of the present disclosure. The changes or adjustments of the relative relationship without a substantial modification to the technical solutions are regarded as being covered by the implementable scope of the present disclosure.

It is to be noted that in the present disclosure, unless specified or limited otherwise, a first feature “on” or “below” a second feature may include an embodiment in which the first feature is in direct contact with the second feature, and may also include an embodiment in which the first feature and the second feature are in indirect contact via an intermediary. Furthermore, a first feature “on,” “above,” or “on top of” a second feature may include an embodiment in which the first feature is right or obliquely “on,” “above,” or “on top of” the second feature, or just means that the first feature is at a height higher than that of the second feature. A first feature “below,” “under,” or “on bottom of”′ a second feature may include an embodiment in which the first feature is right or obliquely “below,” “under,” or “on bottom of” the second feature, or just means that the first feature is at a height lower than that of the second feature.

In addition, in the present disclosure, unless specified or limited otherwise, terms “mounted”, “connected”, “coupled”, “fixed” and so on should be understood in a broad sense, which may be, for example, a fixed connection, a detachable connection or integrated connection, a direct connection or indirect connection by means of an intermediary, an internal communication between two elements or an interaction relationship between two elements. The specific significations of the above terms in the present disclosure may be understood in the light of specific conditions by persons of ordinary skill in the art.

Reference throughout this specification to the terms “an embodiment,” “some embodiments,” “an exemplary embodiment,” “an example,” “a specific example,” or “some examples,” means that a specific feature, structure, material, or characteristic described in connection with the embodiment or example is included in at least one embodiment or example of the present disclosure. The schematic representation of the above terms throughout this specification are not necessarily referring to the same embodiment or example. Furthermore, the specific features, structures, materials, or characteristics set forth may be combined in any suitable manner in one or more embodiments or examples.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. A refrigeration apparatus for a machine room, the refrigeration apparatus comprising a primary heat exchanger and a secondary heat exchanger, wherein both the primary heat exchanger and the secondary heat exchanger are arranged in a first air duct forming an air circuit together with an inner cavity of the machine room, the air circuit is provided for air to flow through, and the secondary heat exchanger is positioned downstream of the primary heat exchanger;
the primary heat exchanger is connected in series to a first refrigeration circuit, the first refrigeration circuit is provided for a first cooling medium to flow through and is cooled down by means of liquid cooling; and
the secondary heat exchanger is connected in series to a second refrigeration circuit, the second refrigeration circuit is provided for a second cooling medium to flow through, and at least a portion of the second refrigeration circuit is refrigerated by means of a compressor.

2. The refrigeration apparatus according to claim 1, wherein the primary heat exchanger has a first inflow end and a first outflow end, and the first inflow end and/or the first outflow end of the primary heat exchanger are provided with a first shut-off valve configured to shut off the first refrigeration circuit when a temperature outside the machine room is lower than a preset temperature.

3. The refrigeration apparatus according to claim 2 further comprising an intermediate heat exchanger, wherein the intermediate heat exchanger is arranged in the first air duct; and
the intermediate heat exchanger is connected in series to a third refrigeration circuit provided for a third cooling medium to flow through, and the third refrigeration circuit is cooled down by means of cooling of air outside the machine room.

4. The refrigeration apparatus according to claim 3, wherein the intermediate heat exchanger has a third inflow end and a third outflow end, and the third inflow end and/or the third outflow end of the secondary heat exchanger are provided with a second shut-off valve configured to switch on the third refrigeration circuit when the temperature outside the machine room is lower than a temperature inside the machine room.

5. The refrigeration apparatus according to claim 4, wherein the third refrigeration circuit comprises a first outdoor heat exchanger and a power pump, the second refrigeration circuit comprises a second outdoor heat exchanger and a compressor, both the first outdoor heat exchanger and the second outdoor heat exchanger are arranged in a second air duct, and two open ends of the second air duct are both communicated with an outer side of the machine room.

6. The refrigeration apparatus according to claim 5, wherein the intermediate heat exchanger is positioned upstream of the secondary heat exchanger; and/or
the second outdoor heat exchanger is positioned upstream of the first outdoor heat exchanger.

7. The refrigeration apparatus according to claim 2, wherein the second refrigeration circuit comprises an outdoor heat exchanger, a compressor, and a fluorine pump; the compressor and the fluorine pump are connected in parallel to the second refrigeration circuit, and the compressor and the fluorine pump are configured to not start up simultaneously;
when a temperature inside the machine room is lower than a first warning temperature and the temperature outside the machine room is lower than the temperature inside the machine room, the fluorine pump is communicated between the secondary heat exchanger and the outdoor heat exchanger; and
when the temperature outside the machine room is higher than the temperature inside the machine room, the compressor is communicated between the secondary heat exchanger and the outdoor heat exchanger.

8. The refrigeration apparatus according to claim 7, wherein the compressor is connected in series between an outflow end of the secondary heat exchanger and an inflow end of the outdoor heat exchanger, and the fluorine pump is connected in series between an outflow end of the outdoor heat exchanger and an inflow end of the secondary heat exchanger; and
two ends of the fluorine pump are connected in parallel to a third shut-off valve, two ends of the compressor are connected in parallel to a fourth shut-off valve, and the third shut-off valve and the fourth shut-off valve do not carry out a shut-off operation simultaneously.

9. The refrigeration apparatus according to claim 2 further comprising a filter, wherein the filter is arranged in the first air duct and is configured to filter air flowing therethrough.

10. A data center comprising a server and a refrigeration apparatus, the refrigeration apparatus comprising a primary heat exchanger and a secondary heat exchanger, wherein both the primary heat exchanger and the secondary heat exchanger are arranged in a first air duct forming an air circuit together with an inner cavity of the machine room, the air circuit is provided for air to flow through, and the secondary heat exchanger is positioned downstream of the primary heat exchanger;
the primary heat exchanger is connected in series to a first refrigeration circuit, the first refrigeration circuit is provided for a first cooling medium to flow through and is cooled down by means of liquid cooling; and
the secondary heat exchanger is connected in series to a second refrigeration circuit, the second refrigeration circuit is provided for a second cooling medium to flow through, and at least a portion of the second refrigeration circuit is refrigerated by means of a compressor;
wherein the server is arranged in the inner cavity of the machine room, and the primary heat exchanger and the secondary heat exchanger of the refrigeration apparatus are both arranged in the first air duct forming the air circuit together with the inner cavity of the machine room.

11. The data center according to claim 10, wherein the primary heat exchanger has a first inflow end and a first outflow end, and the first inflow end and/or the first outflow end of the primary heat exchanger are provided with a first shut-off valve configured to shut off the first refrigeration circuit when a temperature outside the machine room is lower than a preset temperature.

12. The data center according to claim 11 further comprising an intermediate heat exchanger, wherein the intermediate heat exchanger is arranged in the first air duct; and
the intermediate heat exchanger is connected in series to a third refrigeration circuit provided for a third cooling medium to flow through, and the third refrigeration circuit is cooled down by means of cooling of air outside the machine room.

13. The data center according to claim 12, wherein the intermediate heat exchanger has a third inflow end and a third outflow end, and the third inflow end and/or the third outflow end of the secondary heat exchanger are provided with a second shut-off valve configured to switch on the third refrigeration circuit when the temperature outside the machine room is lower than a temperature inside the machine room.

14. The data center according to claim 13, wherein the third refrigeration circuit comprises a first outdoor heat exchanger and a power pump, the second refrigeration circuit comprises a second outdoor heat exchanger and a compressor, both the first outdoor heat exchanger and the second outdoor heat exchanger are arranged in a second air duct, and two open ends of the second air duct are both communicated with an outer side of the machine room.

15. The data center according to claim 14, wherein the intermediate heat exchanger is positioned upstream of the secondary heat exchanger; and/or
the second outdoor heat exchanger is positioned upstream of the first outdoor heat exchanger.

16. The data center according to claim 11, wherein the second refrigeration circuit comprises an outdoor heat exchanger, a compressor, and a fluorine pump; the compressor and the fluorine pump are connected in parallel to the second refrigeration circuit, and the compressor and the fluorine pump are configured to not start up simultaneously;
when a temperature inside the machine room is lower than a first warning temperature and the temperature outside the machine room is lower than the temperature inside the machine room, the fluorine pump is communicated between the secondary heat exchanger and the outdoor heat exchanger; and
when the temperature outside the machine room is higher than the temperature inside the machine room, the compressor is communicated between the secondary heat exchanger and the outdoor heat exchanger.

17. The data center according to claim 16, wherein the compressor is connected in series between an outflow end of the secondary heat exchanger and an inflow end of the outdoor heat exchanger, and the fluorine pump is connected in series between an outflow end of the outdoor heat exchanger and an inflow end of the secondary heat exchanger; and
two ends of the fluorine pump are connected in parallel to a third shut-off valve, two ends of the compressor are connected in parallel to a fourth shut-off valve, and the third shut-off valve and the fourth shut-off valve do not carry out a shut-off operation simultaneously.

18. The data center according to claim 11 further comprising a filter, wherein the filter is arranged in the first air duct and is configured to filter air flowing therethrough.
